(19) United States
(12) Patent Application Publication
(10) Pub. No.: US 2009/0184364 A1
(43) Pub. Date: Jul. 23, 2009

(54) NON-VOLATILE SEMICONDUCTOR STORAGE DEVICE AND METHOD OF MANUFACTURING THE SAME

(75) Inventor: Naozumi Terada, Kawasaki-shi (JP)

Correspondence Address: Gregory Turocy;Amin, Turocy & Calvin, LLP, 24TH Floor, National City Center, 1900 East 9th Street, Cleveland, OH, 44114, US

(73) Assignee: KABUSHIKI KAISHA TOSHIBA, Tokyo (JP)

(21) Appl. No.: 12/349,146

(22) Filed: Jan. 6, 2009

(30) Foreign Application Priority Data
Jan. 7, 2008 (JP) 2008-000705

(51) Int. Cl. H01L 29/792; H01L 21/336

(52) U.S. Cl. 257/326; 438/258; 257/E29.309; 257/E21.423

(57) ABSTRACT

A non-volatile semiconductor storage device includes device regions and device isolation regions that are formed on a semiconductor substrate, with a first direction defined as their longitudinal direction. The non-volatile semiconductor storage device also includes memory cells having a cell transistor formed on the device regions and a selection transistor to select the cell transistor. Each of gate electrode wires provides a common connection between a plurality of memory cells arranged in a line in a second direction, and is arranged to extend in the second direction. Each of the gate electrode wires has a first width on the device regions and a second width larger than the first width on the device isolation regions.

### CROSS REFERENCE TO RELATED APPLICATIONS

This application is based on and claims the benefit of priority from prior Japanese Patent Application No. 2008-705, filed on Jan. 7, 2008, the entire contents of which are incorporated herein by reference.

### BACKGROUND OF THE INVENTION

1. Field of the Invention

The present invention relates to a non-volatile semiconductor storage device and a method of manufacturing the same, and in particular, to a structure of memory cell arrays in flash memory.

2. Description of the Related Art

One of electrically rewritable non-volatile semiconductor storage devices is NOR-type flash memory with a dual-transistor structure. The NOR-type flash memory allows high-speed access as well as write and read operations in one byte basis.

The flash memory with a dual-transistor structure has memory cell arrays with a plurality of memory cells arranged in a matrix. A memory cell includes, as a unit, a cell transistor to store information and a selection gate transistor to select the cell transistor. The cell transistor has a dual-gate structure of a control gate electrode and a floating gate electrode and stores information in a floating gate in a non-volatile manner. The memory cell is formed so that the source region of each cell transistor and the drain region of each selection gate transistor are shared within a device region formed on the surface of the semiconductor substrate. Also, each of the memory cells is formed in such a way that one drain region is shared between neighboring cell transistors and one source region is shared between neighboring selection gate transistors, which are alternately and repeatedly arranged in a line. Columns of the memory cells arranged in a line are isolated from each other by respective device isolation regions formed on the semiconductor substrate using STI (Shallow Trench Isolation). To achieve high integration density in such flash memory, some configurations are known to reduce the distance between the control gate electrodes and the selection gate electrodes by forming control gate electrodes of the cell transistors and selection gate electrodes of the selection gate transistors at the same time, as disclosed in Japanese Patent Laid-Open No. (HEI) 11-330279.

When the interval between two memory cells becomes shorter than a certain distance in the memory cell arrays in the conventional flash memory with a dual-transistor structure, voids may be created in the buried material for an interlayer insulation film. If such voids are created, a conductive material is also diffused and deposited on the voids in the process of depositing the material to form a hole-shaped contact on a drain region shared between two cell transistors. Then, the contacts, which should be electrically isolated from each other, are electrically short-circuited via the material stuck in the voids. To avoid this phenomenon, the distance between the memory cells can conventionally be reduced only to the extent such voids are not formed in the buried material, which would present difficulties in reducing the size of memory cell arrays.

### SUMMARY OF THE INVENTION

One aspect of the present invention provides a non-volatile semiconductor storage device comprising: a plurality of device regions formed on a semiconductor substrate with a first direction defined as their longitudinal direction; device isolation regions formed at positions between the plurality of device regions on the semiconductor substrate to isolate the plurality of device regions; a memory cell array having a plurality of memory cells arranged therein, the plurality of memory cells each including a cell transistor formed on the device regions and a selection transistor to select the cell transistor; contact regions shared by the plurality of memory cells arranged in a line in the first direction; and gate electrode wires, each providing a common connection between the plurality of memory cells arranged in a line in a second direction orthogonal to the first direction, and each arranged to extend in the second direction, the gate electrode wires being formed to have a first width on the device regions and a second width larger than the first width on the device isolation regions.

Another aspect of the present invention provides a non-volatile semiconductor storage device comprising: a plurality of device regions formed on a semiconductor substrate with a first direction defined as their longitudinal direction; device isolation regions formed at positions between the plurality of device regions on the semiconductor substrate to isolate the plurality of device regions; a plurality of memory cell blocks having memory cell units arranged therein, each of the memory cell units including a plurality of cell transistors formed and serially connected to each other on the device regions and a plurality of selection transistors provided on both ends of the serially connected cell transistors to select the cell transistors; contact regions shared by the plurality of selection transistors arranged in a line in the first direction; and gate electrode wires, each providing a common connection between the plurality of selection transistors arranged in a line in a second direction orthogonal to the first direction, and each arranged to extend in the second direction, the gate electrode wires being formed to have a first width on the device regions and a second width larger than the first width on the device isolation regions.

Still another aspect of the present invention provides a method of manufacturing a non-volatile semiconductor storage device, the method comprising: forming, on a semiconductor substrate, a plurality of device regions and device isolation regions formed at positions between the plurality of device regions to isolate the plurality of device regions with a first direction being defined as their longitudinal direction; forming, on the device regions on the semiconductor substrate, a plurality of memory cells each having a cell transistor and a selection transistor connected in series; and forming gate electrode wires, each providing a common connection between the plurality of memory cells arranged in a line in a second direction orthogonal to the first direction, and each arranged to extend in the second direction, the gate electrode wires being formed to have a first width on the device regions and a second width larger than the first width on the device isolation regions.

### BRIEF DESCRIPTION OF THE DRAWINGS

FIG. 1 is an equivalent circuit diagram of a non-volatile semiconductor storage device according to a first embodiment;

FIG. 2 is a plan view of memory cells in the non-volatile semiconductor storage device according to the first embodiment;

FIG. 3A is a cross-sectional view of memory cells in the non-volatile semiconductor storage device according to the first embodiment;

FIG. 3B is a cross-sectional view of memory cells in the non-volatile semiconductor storage device according to the first embodiment;

FIG. 4A illustrates a step of manufacturing the non-volatile semiconductor storage device according to the first embodiment;

FIG. 4B illustrates a step of manufacturing the non-volatile semiconductor storage device according to the first embodiment;

FIG. 5A illustrates a step of manufacturing the non-volatile semiconductor storage device according to the first embodiment;

FIG. 5B illustrates a step of manufacturing the non-volatile semiconductor storage device according to the first embodiment;

FIG. 6A illustrates a step of manufacturing the non-volatile semiconductor storage device according to the first embodiment;

FIG. 6B illustrates a step of manufacturing the non-volatile semiconductor storage device according to the first embodiment;

FIG. 7A illustrates a step of manufacturing the non-volatile semiconductor storage device according to the first embodiment;

FIG. 7B illustrates a step of manufacturing the non-volatile semiconductor storage device according to the first embodiment;

FIG. 8A illustrates a step of manufacturing the non-volatile semiconductor storage device according to the first embodiment;

FIG. 8B illustrates a step of manufacturing the non-volatile semiconductor storage device according to the first embodiment;

FIG. 9A illustrates a step of manufacturing the non-volatile semiconductor storage device according to the first embodiment;

FIG. 9B illustrates a step of manufacturing the non-volatile semiconductor storage device according to the first embodiment;

FIG. 10 is an equivalent circuit diagram of a non-volatile semiconductor storage device according to a second embodiment;

FIG. 11 is a plan view of memory cells in the non-volatile semiconductor storage device according to the second embodiment;

FIG. 12 is a cross-sectional view of memory cells in the non-volatile semiconductor storage device according to the second embodiment; and

FIG. 13 is a cross-sectional view of memory cells in the non-volatile semiconductor storage device according to the second embodiment.

### DETAILED DESCRIPTION OF THE EMBODIMENTS

Embodiments of the present invention will now be described below with reference to the accompanying drawings. As used herein, the term “first conductive-type” refers to “In-type” and “second conductive-type” refers to “p-type”. For the purposes of illustration, the same reference numerals refer to the same components throughout the drawings and description thereof will be omitted with respect to the subsequent drawings.

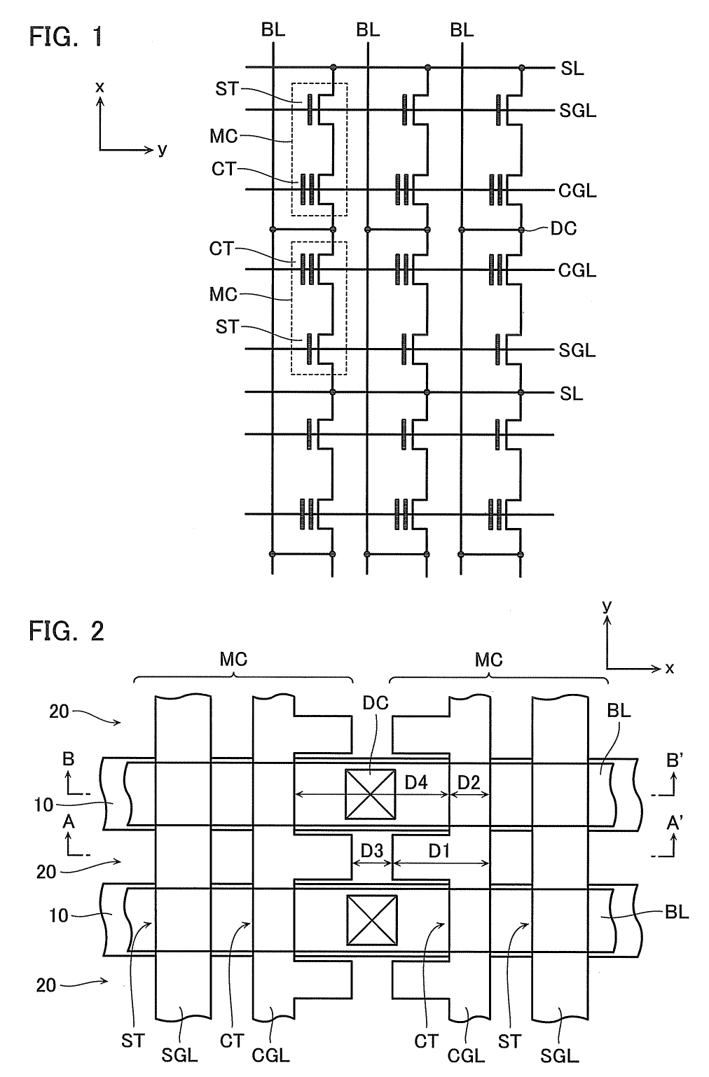

FIG. 1 is an equivalent circuit diagram of memory cell arrays in a non-volatile semiconductor storage device according to a first embodiment of the present invention. The non-volatile semiconductor storage device of this embodiment is configured as NOR-type flash memory with a dual-transistor structure.

As illustrated in FIG. 1, the non-volatile semiconductor storage device of this embodiment has a plurality of memory cells MC arranged in a matrix form. Each of the memory cells MC includes a non-volatile cell transistor CT with a dual-gate structure and a selection gate transistor ST connected in series. The source region of each non-volatile cell transistor CT is shared with the drain region of each selection gate transistor ST.

In the memory cell array, memory cells MC are arranged to have the following parts alternately repeated therein in the column direction (x direction in FIG. 1): one part in which a drain region is shared between two neighboring cell transistors CT, and another part in which a source region is shared between neighboring selection gate transistors ST. In addition, as illustrated in FIG. 1, a plurality of control gate lines CGL are disposed in the row direction (y direction in FIG. 1), through which the control gate electrodes of multiple cell transistors CT arranged in the row direction are commonly connected to each other. Further, a plurality of selection gate lines SGL are disposed in the row direction (y direction in FIG. 1), through which the selection gate electrodes of multiple selection gate transistors ST arranged in the row direction are commonly connected to each other.

In addition, each drain region which is shared between two neighboring cell transistors CT in the column direction (x direction in FIG. 1) is connected to a bit line BL with low resistance via a drain contact DC. That is, the drain region shared between the neighboring cell transistors CT becomes a contact region of the corresponding drain contact DC. A plurality of bit lines BL are disposed in the column direction, each providing a common connection between multiple drain regions arranged in the column direction. In addition, each source region which is shared between two neighboring selection gate transistors ST in the column direction (x direction in FIG. 1) is connected to a source line SL with low resistance. A plurality of source lines SL are disposed in the row direction, each providing a common connection between multiple source regions arranged in the row direction (y direction in FIG. 1). Potentials are provided from outside the memory cell arrays via the source lines SL.

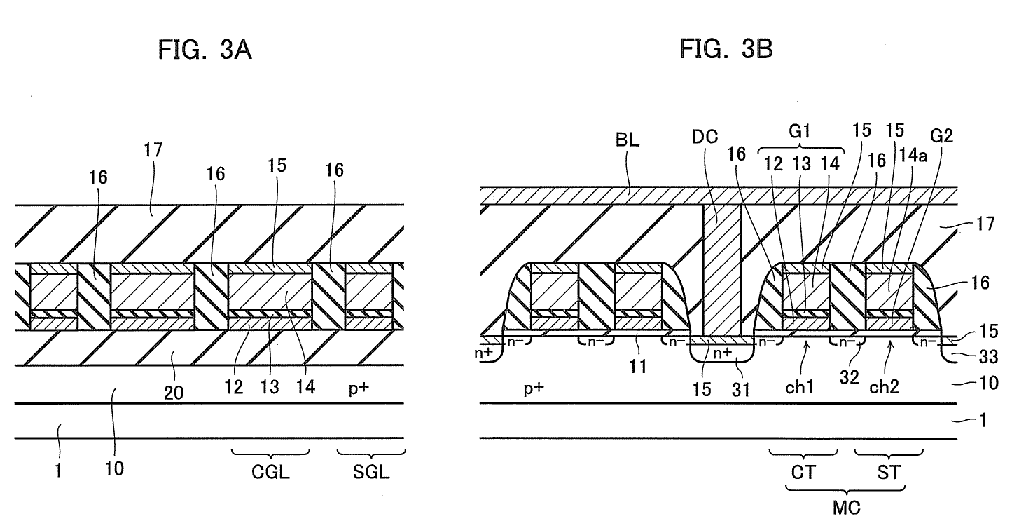

FIG. 2 is a plan view illustrating in part a layout of the memory cell arrays in the non-volatile semiconductor storage device illustrated in FIG. 1. FIG. 3 is a cross-sectional view taken along the lines A-A′ and B-B′ of FIG. 2. FIG. 3A is a cross-sectional view taken along the line A-A′ of FIG. 2, and FIG. 3B is a cross-sectional view taken along the line B-B′ of FIG. 2.

The memory cells MC in the non-volatile semiconductor storage device illustrated in FIGS. 2 and 3 are formed on a plurality of device regions 10 (in this embodiment, p⁺ type semiconductor layers formed on the surface of the semiconductor substrate 1) that are formed on the surface of a semiconductor substrate 1 (in this embodiment, p-type silicon (Si) substrate), wherein the x direction in FIG. 2 is defined as the longitudinal direction. As illustrated in FIGS. 2 and 3, the memory cells MC are arranged in such a way that a source region 32 of each cell transistor CT and a drain region 32 of each selection gate transistor ST are shared on a device region 10.

As illustrated in FIG. 3, a cell transistor CT has diffusion regions 31 and 32 for source and drain as well as a channel region ch1 that are formed on the device region. A gate electrode G1 with a stacked structure is formed on the channel region ch1 via a gate insulation film (tunnel insulation film) 11. The gate electrode G1 with a stacked structure includes three layers of a floating gate electrode 12, an inter-gate insulation film 13, and a control gate electrode 14. In this embodiment, for example, the floating gate electrode 12 includes two layers of polysilicon films, and the inter-gate insulation film 13 includes an ONO film (lamination film of silicon oxide/silicon nitride/silicon oxide). In addition, for example, the control gate electrode 14 includes a polysilicon film, on which surface a metal silicide layer 15 is formed. Further, each control gate line CGL is configured to provide a common connection between those control gate electrodes 14 of corresponding cell transistors CT aligned in the row direction.

As in the cell transistor CT, a selection gate transistor ST has diffusion regions 32 and 33 for source and drain as well as a channel region ch2 that are formed on the device regions 10, as illustrated in FIG. 3. A gate electrode G2 is formed on the channel region ch2 via a gate insulation film 11. The selection gate transistor ST has a lower-layer gate electrode used as a selection gate electrode G2. Further, each selection gate line SGL is configured to provide a common connection between those selection gate electrodes G2 of corresponding selection gate transistors ST aligned in the row direction.

A metal silicide layer 15 is formed on the drain region 31 of each cell transistor CT, the source region 33 of each selection gate transistor ST, each control gate electrode 14, and an upper-layer gate electrode 14a of each selection gate transistor ST, respectively. In addition, sidewall insulation films 16 are formed on the respective sidewalls of the gate electrodes G1 and G2 for each cell transistor CT and selection gate transistor ST. In the memory cells MC, for example, the space between each cell transistor CT and each selection gate transistor ST is filled up with the sidewall insulation film 16.

In addition, as illustrated in FIG. 3, the cell transistors CT and the selection gate transistors ST are covered with an interlayer insulation film 17. Contact holes are opened through the interlayer insulation film 17 on a plurality of drain regions 31 shared between the corresponding cell transistors CT. The contact holes are filled up with metal such as tungsten (W) to form a plurality of drain contacts DC in contact with respective drain regions 31. In addition, a plurality of bit lines BL with metal such as tungsten (W) are disposed in the column direction on the interlayer insulation film 17, each providing a common connection between those drain contacts DC in the same column. Further, although not illustrated in FIG. 3, a plurality of wires, e.g., source lines SL, which is configured with tungsten and in contact with the respective source regions 33 are disposed in the row direction on the respective source regions 33 that are shared between the corresponding selection gate transistors ST.

According to the memory cell arrays of this embodiment, the device regions 10 are isolated from each other in the column direction by device isolation regions 20 with an STI (Shallow Trench Isolation) structure. As in the device regions 10, the device isolation regions 20 are formed at positions between the corresponding device regions 10 on the semiconductor substrate 1, with the x direction in FIG. 2 defined as their longitudinal direction. The control gate lines CGL and the selection gate lines SGL are disposed across the respective device isolation regions 20. In addition, each control gate line CGL has a width D1 in the x direction on the line A-A1 of FIG. 2 that is larger than a width D2 in the x direction on the line B-B′. Further, the width D1 of the control gate line CGL is set to a distance such that an interval D3 between the control gate lines CGL is filled up with the sidewall insulation film 16. Moreover, as illustrated in FIGS. 2 and 3, the control gate lines CGL are formed such that side surfaces thereof facing the drain contact DC has a concavo-convex pattern in plan view. Since the control gate lines CGL have convex portions with side surfaces facing the drain contacts DC that protrude in the x direction on the device isolation regions 20, they are formed to have the width D1 on the respective device isolation regions 20.

In the non-volatile semiconductor storage device so configured, the following description is made to explain the operation to write data to the cell transistor CT selected by a selection gate transistor ST. In the data write operation, it is assumed that a ground potential is provided to the device region 10 of the selected cell transistor CT and to the source region 32 of the selected cell transistor CT via the selection gate transistor ST. Then, a predetermined potential is provided from external circuitry to the control gate line CGL and the bit line BL connected to the drain region 31 of the selected cell transistor CT, such that a maximum generation efficiency of hot electrons can be obtained. Thus, electrons are injected into the floating gate electrode 12 with the channel hot electron injection, by which data is written to the cell transistor CT.

In the non-volatile semiconductor storage device according to this embodiment, the corresponding control gate lines CGL expand in width (as indicated by width D1) on the device isolation regions 20 such that they protrude in the opposing direction toward the drain contacts DC. Thus, the control gate lines CGL are formed with the interval D3 on the device isolation regions 20 that is smaller than the interval D4 on the device regions 10. In this embodiment, the control gate lines CGL are spaced apart from each other by almost the same distance with that between the control gate lines CGL and the selection gate lines SGL in each memory cell MC. In addition, as illustrated in FIG. 3, the interval D3 between the control gate lines CGL on the device isolation regions 20 is set to such a distance that can be filled up with the sidewall insulation film 16. Further, as illustrated in FIGS. 2 and 3, those side surfaces of the control gate lines CGL that face the drain contacts DC are formed to have convex portions that protrude in the x direction on the device isolation regions 20.

If the control gate lines CGL are formed with a constant width (e.g., D2) on the device regions 10 and the device isolation regions 20, then corresponding two control gate lines CGL are also spaced apart by a constant interval (e.g., D4) on the device isolation regions 20. If the corresponding two control gate lines CGL are formed at the constant interval D4, then it is required to fill up the space between the control gate lines CGL with the interlayer insulation film 17 since it cannot be filled up with the sidewall insulation film 16. Wherein the smaller the distance between memory cells MC to reduce the area of memory cell arrays, the smaller the interval between the two control gate lines CGL opposing across a drain contact DC. In this case, it becomes more difficult to fill up the interval between the corresponding two control gate lines CGL with the interlayer insulation film 17, which could create voids therein. If a conductive material is deposited within the voids formed between the control gate lines CGL on the device isolation regions 20, then the two neighboring drain contacts DC in the row direction are short-circuited, which would lead to degradation in reliability of the non-volatile semiconductor storage device.

According to the configuration of this embodiment, it is ensured that the space between the control gate lines CGL can be filled up with the sidewall insulation film 16, since the control gate lines CGL are formed with a smaller interval D3 on the device isolation regions 20. This may prevent the creation of voids between the drain contacts DC. It is possible to avoid a short circuit between the drain contacts DC when providing a potential to the drain region 31 from the bit line BL via the drain contact DC in write operations, because no void is created between the neighboring drain contacts DC in the row direction. Even if the distance between memory cells MC is reduced, the creation of voids may be prevented and the size of memory cell arrays may be reduced.

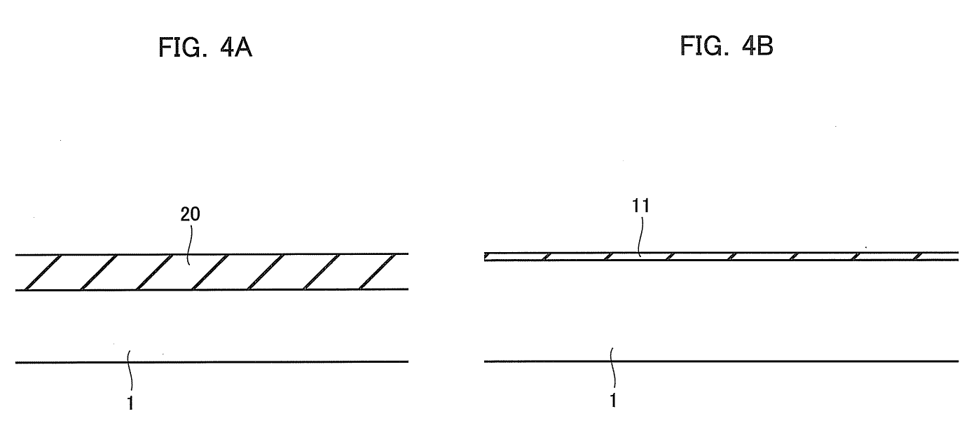

Referring now to FIGS. 4 to 9, a method of manufacturing the non-volatile semiconductor storage device according to the first embodiment will be described below. FIGS. 4 to 9 illustrate manufacturing steps with respect to the cross-section taken along the lines A-A′ and B-B′ of FIG. 2, respectively. FIGS. 4A, 5A, 6A, 7A, 8A and 9A illustrate manufacturing steps as viewed in a cross-section taken along the line A-A′ of FIG. 2, while FIGS. 4B, 5B, 6B, 7B, 8B and 9B illustrate those as viewed in a cross-section taken along the line B-B′ of FIG. 2.

Firstly, as illustrated in FIG. 4B, a gate insulation film 11 is formed on the entire surface of the semiconductor substrate 1 (e.g., p-type silicon (Si) substrate). In addition, as illustrated in FIG. 4A, the surface of the semiconductor substrate 1 is etched by anisotropic etching using an etching mask to form a plurality of trenches in the column direction. Then, an insulation film is embedded in each trench, thereby forming a device isolation region 20 with an STI (Shallow Trench Isolation) structure.

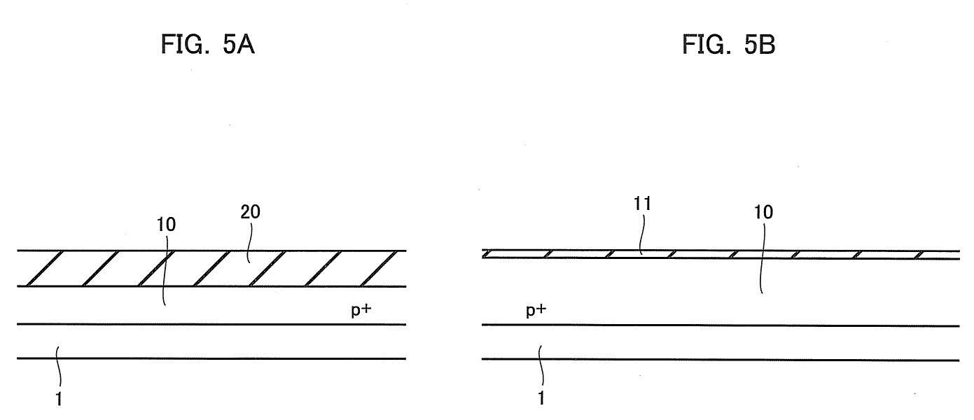

Then, as illustrated in FIGS. 5A and 5B, channel ion injection is performed to form a device region 10 on the semiconductor substrate 1 (in this embodiment, a p⁺ type semiconductor layer formed on the surface of the semiconductor substrate).

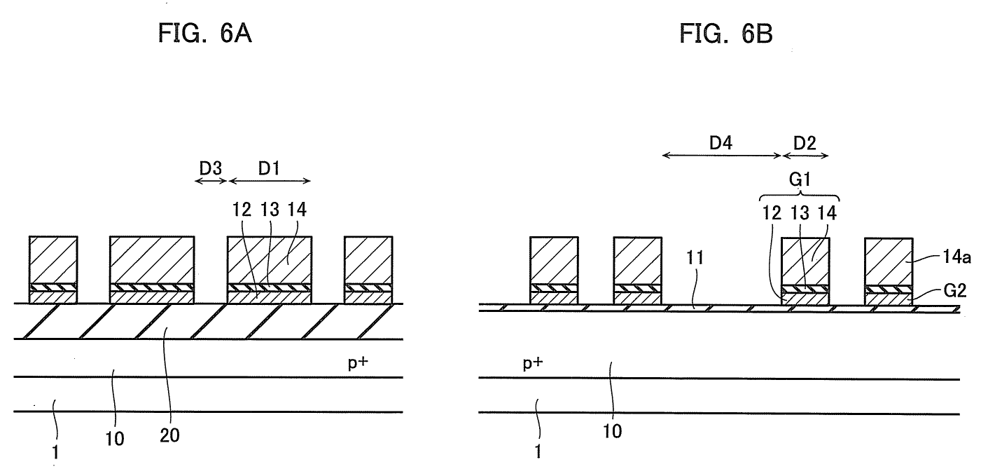

Then, as illustrated in FIGS. 6A and 6B, a conductive film (e.g., polysilicon film), an insulation film (e.g., an insulation film with a laminated structure, such as an ONO film), and a conductive film (e.g., polysilicon film) are sequentially deposited on the entire surface, each with a film thickness of on the order of 100 to 200 nm. Note that, for example, n-type impurities are introduced in the polysilicon films as impurities. Then, a mask material (e.g., oxide film) is further deposited thereon and a resist film is applied to the entire surface. After the resist film is patterned to a certain shape, anisotropic etching is performed to form a plurality of apertures in the mask material. The mask material is used as a mask to etch the laminated structure of a polysilicon film, an insulation film, and a polysilicon film to a certain shape. As a result, gate electrodes G1 with a stacked structure (floating gate electrodes 12 and control gate electrodes 14 of cell transistors CT) are formed on the device region 10. Similarly, gate electrodes G2 and upper-layer gate electrodes 14a of selection gate transistors ST are formed. At this moment, control gate lines CGL are formed in such a way that the corresponding control gate lines CGL expand in width (as indicated by width D1) on the device isolation regions 20 such that they protrude in the opposing direction, and hence the interval D3 on the device isolation regions 20 is smaller than the interval D4 on the device regions 10.

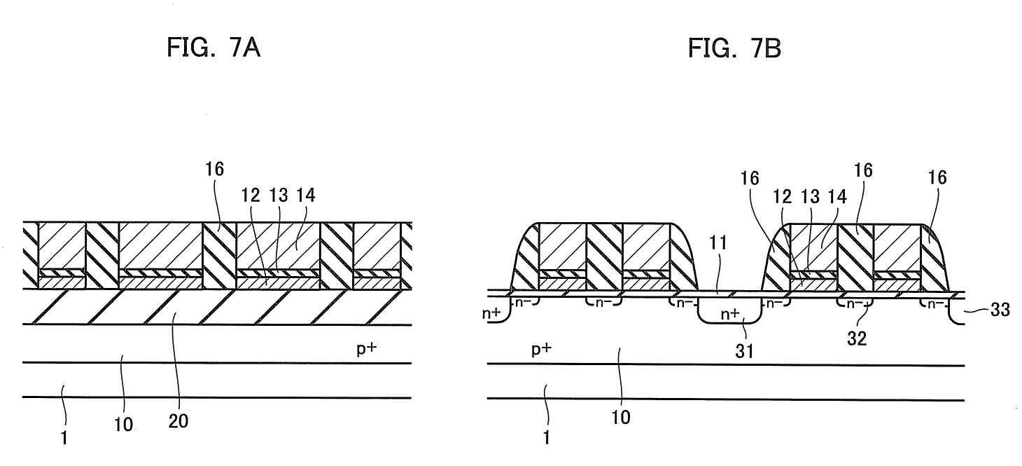

Then, as illustrated in FIG. 7B, lightly-doped shallow diffusion layers (n type semiconductor regions) are formed by ion injection in the source and drain regions so that the cell transistors CT and the selection gate transistors ST have an LDD (Lightly Doped Drain) structure. Then, after an insulation film is deposited on the entire surface, anisotropic etching is performed to form gate-sidewall insulation films 16 on the respective sidewalls of the cell transistors CT and the selection gate transistors ST. At this moment, as illustrated in FIG. 7A, the sidewall insulation films 16 are formed to fill up the space between the opposing control gate lines CGL on the device isolation region 20. Thereafter, highly-doped deep diffusion layers (n⁺ type semiconductor regions) are formed by ion injection in the drain regions 31 and the source regions 33 on the both lower ends of the gate electrodes G1 and G2.

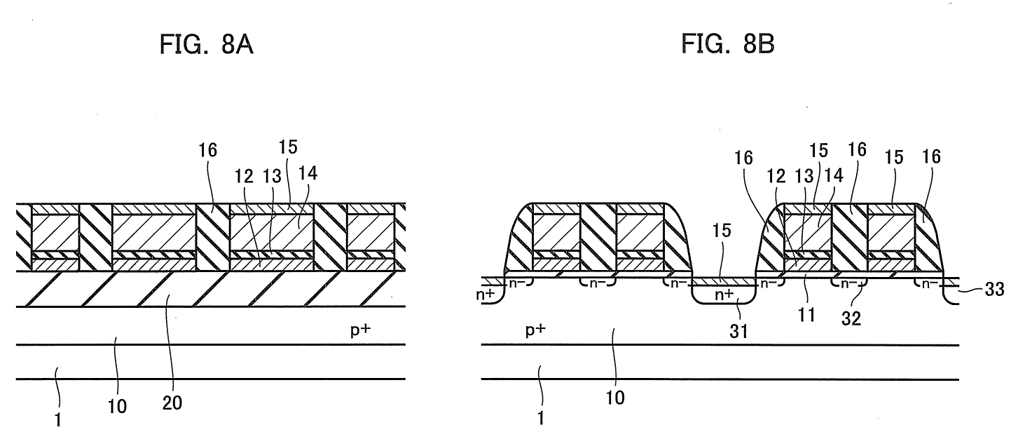

Then, as illustrated in FIGS. 8A and 8B, those portions of the gate insulation film 11 are partially removed by etching that reside on the areas for providing contacts in the drain regions 31 and the source regions 33. In addition, polysilicon layers are also partially removed by etching that reside on the top portions of the cell transistors CT, the selection gate transistors ST, the control gate lines CGL, and the selection gate lines SGL. Then, to provide lower contact resistance with respect to the drain regions 31 and the source regions 33 and lower wiring resistance of gate wires, a thin film of refractory metal, such as cobalt (Co) or nickel (Ni), is sputter deposited on the entire surface. Thereafter, heating process is performed to form a metal silicide layer 15 on the drain region 31 of each cell transistor CT, the source region 33 of each selection gate transistor ST, each control gate electrode 14, and the upper-layer gate electrode 14a of each selection gate transistor ST, respectively. Similarly, a metal silicide layer 15 is formed on the control gate line CGL and the selection gate line SGL on each device isolation region 20, respectively. Meanwhile, unreacted metal films are removed at subsequent steps.

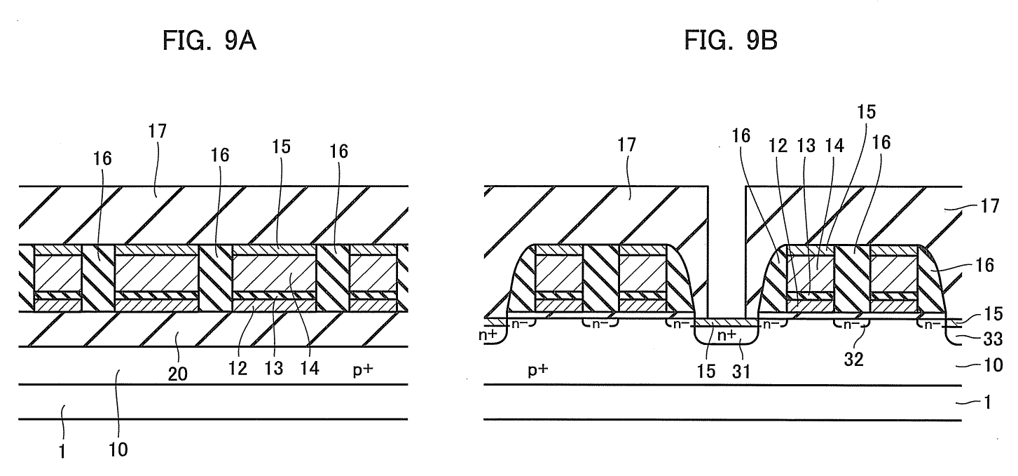

Then, as illustrated in FIGS. 9A and 9B, an interlayer insulation film 17 of, e.g., silicon oxide is deposited by the Low Pressure Chemical Vapor Deposition (LPCVD) method. After reflowing the interlayer insulation film 17, the interlayer insulation film 17 is polished and flattened by CMP (Chemical Mechanical Polishing) to an extent that the gate electrodes are not exposed. Then, contact holes are formed through the interlayer insulation film 17 on the drain regions 31 shared by the corresponding cell transistors CT, using lithography and dry etching processes.

Then, as illustrated in FIGS. 3A and 3B, a metallic conductive film, e.g., tungsten (W) is embedded in the contact holes to form drain contacts DC for connecting bit lines BL. In this embodiment, barrier metals are formed within the contact holes, in which tungsten is embedded. Then, drain contacts DC are formed by removing those portions of the conductive film by CMP polishing that are exposed on the interlayer insulation film 17. Then, wiring metal films are deposited and patterned thereon to form bit lines BL. In this way, the non-volatile semiconductor storage device according to this embodiment is formed as illustrated in FIG. 3. Thereafter, upper wiring layers and passivation layers are formed (not illustrated).

Through the above-mentioned manufacturing method, the gate electrodes of the cell transistors CT and the selection gate transistors ST may be formed, while the control gate lines CGL may be formed to expand in width on the device isolation regions 20 such that they protrude in the opposing direction at the side of the drain regions. Then, sidewall insulation films may be formed on the respective sidewalls of the cell transistors CT and the selection gate transistors ST and the space between the opposing control gate lines CGL on the device isolation regions 20 may be filled up with the sidewall insulation film 16. It is assured that the space between the control gate lines CGL on the device isolation regions 20 is filled up with the sidewall insulation film 16, and hence the creation of voids between the drain contacts can be avoided without increase in number of manufacturing steps.

While the non-volatile semiconductor storage device has been described as NOR-type flash memory in the first embodiment, it will be appreciated that the described embodiment is equally applicable to other flash memory containing characteristics associated with NAND-type flash memory.

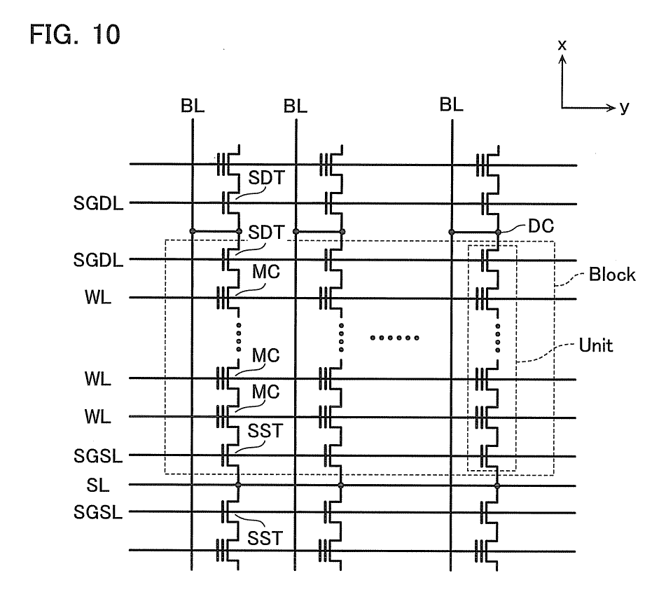

FIG. 10 is an equivalent circuit diagram of memory cell arrays in a non-volatile semiconductor storage device according to a second embodiment of the present invention. The non-volatile semiconductor storage device of this embodiment is configured as NAND-type flash memory.

As illustrated in FIG. 10, one memory cell unit includes a plurality of memory cells MC connected in series, a source-side selection transistor SST serially connected to one end (source side) of the memory cells MC, and a drain-side selection transistor SDT serially connected to the other end (drain side).

There are a plurality of these units arranged in the row direction (y direction in FIG. 10), which in turn configure one block. Those memory cells connected to the same word line in one block are taken as one page, which is the unit of data write and read operations. There are a plurality of blocks arranged in the column direction (x direction in FIG. 10). On each memory cell array, blocks are arranged to have the following parts alternately repeated in the column direction (x direction in FIG. 10): one part in which a drain region is shared between two neighboring drain-side selection transistors SDT, and another part in which a source region is shared between neighboring source-side selection transistors SST.

A plurality of word lines WL are disposed in the row direction (y direction in FIG. 10), each providing a common connection between those gate electrodes of multiple memory cells MC arranged in the row direction. In addition, a plurality of source-side selection gate lines SGSL are arranged in the row direction (y direction in FIG. 10), each providing a common connection between those gate terminals of multiple source-side selection transistors SST arranged in the row direction. Similarly, a plurality of source lines SL are disposed in the row direction (y direction in FIG. 10), each providing a common connection between those source terminals of multiple source-side selection transistors SST arranged in the row direction. A plurality of drain-side selection gate lines SGDL are disposed in the row direction (y direction in FIG. 10), each providing a common connection between those gate terminals of multiple drain-side selection transistors SDT arranged in the row direction. In addition, a plurality of bit lines BL are connected via the drain contacts DC, each providing a common connection between those drain terminals of the drain-side selection transistors SDT arranged in the column direction (x direction in FIG. 10).

The source-side selection gate lines SGSL and the drain-side selection gate lines SGDL are used to on-off control the selection transistors SST and SDT. The source-side selection transistors SST and the drain-side selection transistors SDT function as gates for supplying a certain potential to the memory cells MC in the respective units when writing and reading data, and so on.

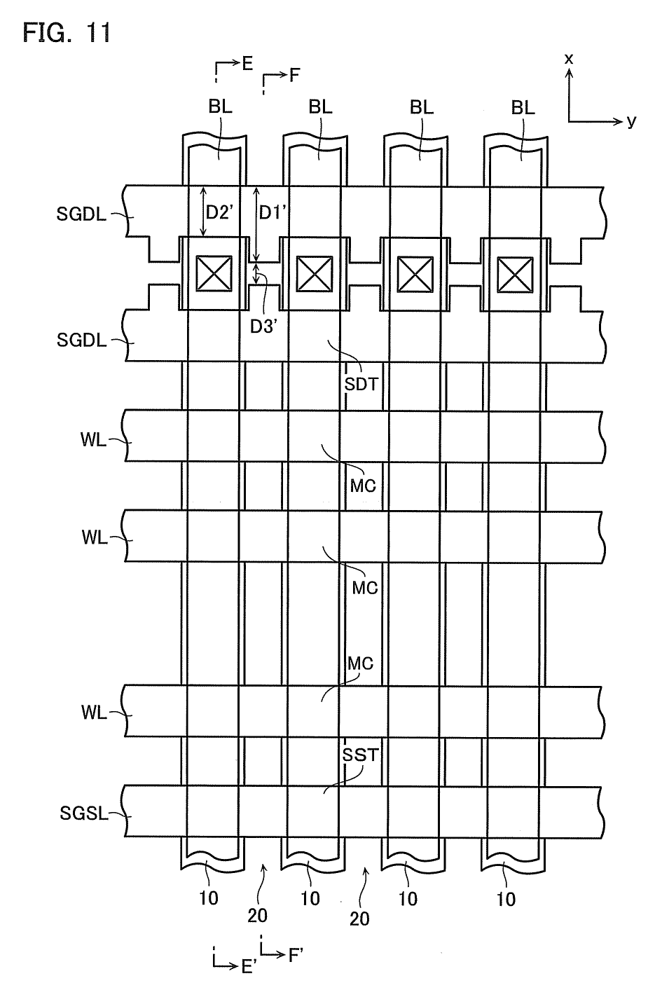

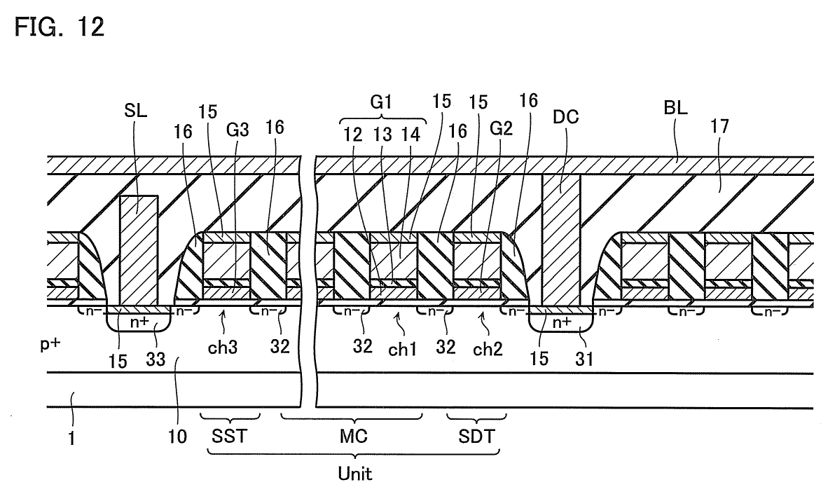

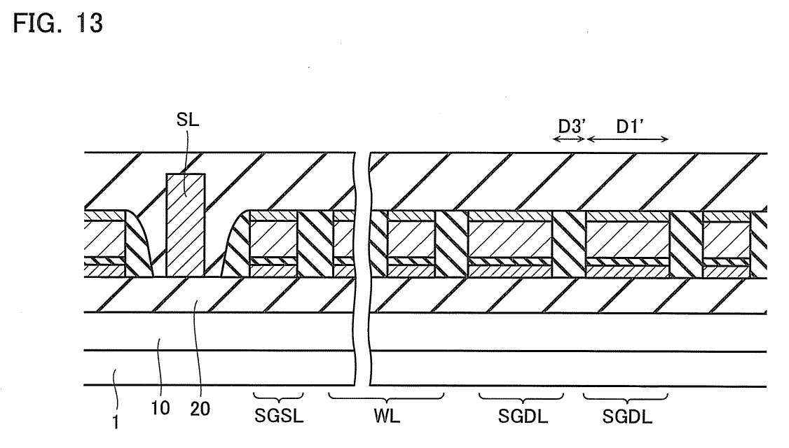

FIG. 11 is a plan view illustrating in part a layout of the memory cell arrays in the non-volatile semiconductor storage device illustrated in FIG. 10. FIG. 12 is a cross-sectional view taken along the line E-E′ of FIG. 11. FIG. 13 is a cross-sectional view taken along the line F-F′ of FIG. 11.

The memory cells MC in the non-volatile semiconductor storage device illustrated in FIGS. 11 to 13 are formed on the surfaces of a plurality of device regions 10 (in this embodiment, p⁺ type semiconductor layers formed on the semiconductor substrate 1) that are formed on the surface of a semiconductor substrate 1 (in this embodiment, p-type silicon (Si) substrate), wherein the x direction in FIG. 11 is defined as the longitudinal direction. As illustrated in FIGS. 11 to 13, each unit is formed to have a plurality of memory cells MC connected in series on a device region 10, a source-side selection transistor SST connected to one end (source side) of the memory cells MC, and a drain-side selection transistor SDT connected to the other end (drain side).

As illustrated in FIG. 12, a memory cell MC has diffusion regions 32 for source and drain as well as a channel region ch1 that are formed on the device region. A gate electrode G1 with a stacked structure is formed on the channel region ch1 via a gate insulation film (tunnel insulation film) 11. The gate electrode G1 includes three layers of a floating gate electrode 12, an inter-gate insulation film 13, and a control gate electrode 14. In this embodiment, for example, the floating gate electrode 12 includes two layers of polysilicon films, and the inter-gate insulation film 13 includes an ONO film (lamination film of silicon oxide/silicon nitride/silicon oxide). In addition, for example, the control gate electrode 14 includes a polysilicon film, on which surface a metal silicide layer 15 is formed. Further, each word line WL is configured to provide a common connection between those control gate electrodes 14 of the memory cells MC aligned in the row direction.

In addition, as illustrated in FIG. 12, a drain-side selection transistor SDT has diffusion regions 31 and 32 for source and drain as well as a channel region ch2 that are formed on the device region 10. A gate electrode G2 is formed on the channel region ch2 via the gate insulation film 11. The drain-side selection transistor SDT has a lower-layer gate electrode used as a selection gate electrode G2. In addition, each drain-side selection gate line SGDL is configured to provide a common connection between those selection gate electrodes G2 of the drain-side selection transistors SDT aligned in the row direction.

In addition, as illustrated in FIG. 12, a source-side selection transistor SST has diffusion regions 32 and 33 for source and drain as well as a channel region ch3 that are formed on the device region 10. A gate electrode G3 is formed on the channel region ch3 via the gate insulation film 11. The source-side selection transistor SST has a lower-layer gate electrode used as a selection gate electrode G3. In addition, each source-side selection gate line SGSL is configured to provide a common connection between those selection gate electrodes G3 of the source-side selection transistors SST aligned in the row direction.

A metal silicide layer 15 is formed on the drain region 31 of each drain-side selection transistor SDT, the source region 33 of each source-side selection transistor SST, and each control gate electrode 14, respectively. In addition, sidewall insulation films 16 are formed on the respective sidewalls of the source-side selection transistor SST and the drain-side selection transistor SDT and between transistors in the unit.

In addition, as illustrated in FIG. 12, the memory cell MC and the selection transistors SST and SDT are covered with an interlayer insulation film 17. Contact holes are opened through the interlayer insulation film 17 on a plurality of drain regions 31 shared between the corresponding drain-side selection transistors SDT. The contact holes are filled up with metal such as tungsten (W) to form a plurality of drain contacts DC in contact with respective drain regions 31. In addition, a plurality of bit lines BL with metal such as tungsten (W) are disposed in the column direction on the interlayer insulation film 17, each providing a common connection between those drain contacts DC in the same column. Further, a plurality of wires, e.g., source lines SL, which is configured with tungsten and in contact with the respective source regions 33 are disposed in the row direction on the respective source regions 33 that are shared between the corresponding source-side selection transistors SST.

According to the memory cell arrays of this embodiment, the device regions 10 are isolated from each other in the column direction by device isolation regions 20 with an STI (Shallow Trench Isolation) structure. As in the device regions 10, the device isolation regions 20 are formed at positions between the corresponding device regions 10 on the semiconductor substrate 1, wherein the x direction in FIG. 11 is defined as the longitudinal direction. The source lines SL, the source-side selection gate lines SGSL, the drain-side selection gate lines SGDL, and the word lines WL are disposed across the respective device isolation regions 20.

In addition, as illustrated in FIGS. 11 and 13, each drain-side selection gate line SGDL has a width D1 in the x direction on the line F-F′ that is larger than a width D2′ in the x direction on the line E-E′. Further, the width D1′ of the drain-side selection gate line SGDL is set to a distance such that an interval D3′ between the drain-side selection gate lines SGDL is filled up with the sidewall insulation film 16.

In the non-volatile semiconductor storage device so configured, it is also assured that the space between the drain-side selection gate lines SGDL is filled up with the sidewall insulation film 16 since the drain-side selection gate lines SGDL have smaller interval D3′ on the device isolation regions 20. This may avoid the creation of voids between the drain contacts DC. It is possible to avoid a short circuit between the drain contacts DC when providing a potential to the drain region 31 from the bit line BL via the drain contact DC in write operations, because no void is created between the neighboring drain contacts DC in the row direction. Even if the distance between memory cells MC is reduced, the creation of voids may be prevented and the size of memory cell arrays may be reduced.

While embodiments of the present invention have been described, the present invention is not intended to be limited to the disclosed embodiments and various other changes, additions or the like may be made thereto without departing from the spirit of the invention. For example, while the first embodiment has been described in the context of both the cell transistors CT and the selection gate transistors ST having an LDD structure, both transistors may not have any LDD structure. In this case, after stacked gate electrodes of the cell transistors CT and the selection gate transistors ST are formed, n⁺ type semiconductor regions (drain and source regions) are formed by ion injection on the surface of the silicon substrate corresponding to the both lower ends of the laminated gate electrodes. This configuration also offers the same advantages as the first embodiment.

What is claimed is:

1. A non-volatile semiconductor storage device comprising:
a plurality of device regions formed on a semiconductor substrate with a first direction defined as their longitudinal direction;
device isolation regions formed at positions between the plurality of device regions on the semiconductor substrate to isolate the plurality of device regions;
a memory cell array having a plurality of memory cells arranged therein, the plurality of memory cells each including a cell transistor formed on the device regions and a selection transistor to select the cell transistor;
contact regions shared by the plurality of memory cells arranged in a line in the first direction; and
gate electrode wires, each providing a common connection between the plurality of memory cells arranged in a line in a second direction orthogonal to the first direction, and each arranged to extend in the second direction,
the gate electrode wires being formed to have a first width on the device regions and a second width larger than the first width on the device isolation regions.

2. The non-volatile semiconductor storage device according to claim 1, wherein
the gate electrode wires have sidewall insulation films on their side surfaces, and
the second width is set to a magnitude on the device isolation regions such that gaps between the gate electrode wires are filled up with the sidewall insulation films.

3. The non-volatile semiconductor storage device according to claim 1, wherein
the gate electrode wires each has, on its side surface facing the contact regions, convex portions protruding in the first direction on the device isolation regions, so that the gate electrode wires are formed to have a second width on the device isolation regions.

4. The non-volatile semiconductor storage device according to claim 1, wherein
the cell transistor has a stacked gate structure resulting from stack of a floating gate electrode, an inter-gate insulation film, and a control gate electrode,
and the control gate electrode are composed of polysilicon with a silicided surface.

5. The non-volatile semiconductor storage device according to claim 1, wherein
gaps between the gate electrode wires formed to have the second width are filled up with sidewall insulation films, and
gaps between the gate electrode wires formed to have the first width are filled up with the sidewall insulation films and interlayer insulation films.

6. The non-volatile semiconductor storage device according to claim 1, wherein
the cell transistor and the selection transistor each has a source region and a drain region, and the source region and the drain region each has a diffusion layer of high impurity concentration and an LDD region of lower impurity concentration than the diffusion layer.

7. The non-volatile semiconductor storage device according to claim 1, wherein
the contact regions have silicided surfaces.

8. A non-volatile semiconductor storage device comprising:
a plurality of device regions formed on a semiconductor substrate with a first direction defined as their longitudinal direction;
device isolation regions formed at positions between the plurality of device regions on the semiconductor substrate to isolate the plurality of device regions;
a plurality of memory cell blocks having memory cell units arranged therein, each of the memory cell units including a plurality of cell transistors formed and serially connected to each other on the device regions and a plurality of selection transistors provided on both ends of the serially connected cell transistors to select the cell transistors;
contact regions shared by the plurality of selection transistors arranged in a line in the first direction; and
gate electrode wires, each providing a common connection between the plurality of selection transistors arranged in a line in a second direction orthogonal to the first direction, and each arranged to extend in the second direction,
the gate electrode wires being formed to have a first width on the device regions and a second width larger than the first width on the device isolation regions.

9. The non-volatile semiconductor storage device according to claim 8, wherein
the gate electrode wires have sidewall insulation films on their side surfaces, and
the second width is set to a magnitude on the device isolation regions such that gaps between the gate electrode wires are filled up with the sidewall insulation films.

10. The non-volatile semiconductor storage device according to claim 8, wherein
the gate electrode wires each has, on its side surface facing the contact regions, convex portions protruding in the first direction on the device isolation regions, so that the gate electrode wires are formed to have a second width on the device isolation regions.

11. The non-volatile semiconductor storage device according to claim 8, wherein
the cell transistor has a stacked gate structure resulting from stack of a floating gate electrode, an inter-gate insulation film, and a control gate electrode,
and the control gate electrode are composed of polysilicon with a silicided surface.

12. The non-volatile semiconductor storage device according to claim 8, wherein
gaps between the gate electrode wires formed to have the second width are filled up with sidewall insulation films, and
gaps between the gate electrode wires formed to have the first width are filled up with the sidewall insulation films and interlayer insulation films.

13. The non-volatile semiconductor storage device according to claim 8, wherein
the cell transistor and the selection transistor each has a source region and a drain region, and the source region and the drain region each has a diffusion layer of high impurity concentration and an LDD region of lower impurity concentration than the diffusion layer.

14. The non-volatile semiconductor storage device according to claim 8, wherein
the contact regions have silicided surfaces.

15. A method of manufacturing a non-volatile semiconductor storage device, the method comprising:
forming, on a semiconductor substrate, a plurality of device regions and device isolation regions formed at positions between the plurality of device regions to isolate the plurality of device regions with a first direction being defined as their longitudinal direction;
forming, on the device regions on the semiconductor substrate, a plurality of memory cells each having a cell transistor and a selection transistor connected in series; and
forming gate electrode wires, each providing a common connection between the plurality of memory cells arranged in a line in a second direction orthogonal to the first direction, and each arranged to extend in the second direction,
the gate electrode wires being formed to have a first width on the device regions and a second width larger than the first width on the device isolation regions.

16. The method of manufacturing the non-volatile semiconductor storage device according to claim 15, the method further comprising:
forming sidewall insulation films on side surfaces of the gate electrode wires,
wherein the gate electrode wires are formed with the second width being set to a magnitude on the device isolation regions such that gaps between the gate electrode wires are filled up with the sidewall insulation films.

17. The method of manufacturing the non-volatile semiconductor storage device according to claim 15, the method further comprising:
forming contact regions shared by the plurality of memory cells arranged in a line in the first direction,
wherein the gate electrode wires each has, on its side surface facing the contact regions, convex portions protruding in the first direction on the device isolation regions, so that the gate electrode wires are formed to have a second width on the device isolation regions.

18. The method of manufacturing the non-volatile semiconductor storage device according to claim 15, wherein
the cell transistors are formed as a stacked gate structure resulting from stack of a floating gate electrode, an inter-gate insulation film, and a control gate electrode.

19. The method of manufacturing the non-volatile semiconductor storage device according to claim 15, the method further comprising:
filling up gaps between the gate electrode wires formed to have the second width with sidewall insulation films, and
filling up gaps between the gate electrode wires formed to have the first width with the sidewall insulation films and interlayer insulation films.

20. The method of manufacturing the non-volatile semiconductor storage device according to claim 15, wherein
the cell transistor and the selection transistor are formed to have a source region and a drain region with a diffusion layer of high impurity concentration and an LDD region of lower impurity concentration than the diffusion layer.
